(19) United States
(12) Patent Application Publication
(10) Pub. No.: US 2012/0300155 A1
(43) Pub. Date: Nov. 29, 2012

(54) PHOSPHORS

(75) Inventors: Holger Winkler, Darmstadt (DE); Peter Barnekow, Hockenheim (DE); Clemens Kuehn, Darmstadt (DE); Ralf Petry, Griesheim (DE); Tim Vosgroene, Ober-Ramstadt (DE); Thomas Juestel, Witten (DE); Dominik Uhlich, Steinfurt (DE); Arturas Katelnikovas, Steinfurt (DE); Danuta Dutczak, Steinfurt (DE)

(73) Assignee: MERCK PATENT GESELLSCHAFT MIT BESCHRANKTER HAFTUNG, Darmstadt (DE)

(21) Appl. No.: 13/575,659

(22) PCT Filed: Dec. 28, 2010
(86) PCT No.: PCT/EP10/07954

§ 371 Date: Jul. 27, 2012

(30) Foreign Application Priority Data
Jan. 29, 2010 (EP) 10000933.1

(51) Int. Cl. G02F 1/13357; C09K 11/86; C09K 11/79; H01L 33/50; F21V 9/16

(52) U.S. Cl. 349/70; 257/98; 362/84; 252/301.4 R; 252/301.4 H; 257/E33.061

(57) ABSTRACT

The invention relates to compounds of the formula (I), A_{2-0.5y-χ}EuₓSi₅N_{8-y}O_{y} (I), where A stands for one or more elements selected from Ca, Sr, Ba, and x stands for a value from the range 0.005 to 1, and y stands for a value from the range 0.01 to 3, to mixtures thereof, to a process for the preparation of these phosphors and mixtures, and to the use thereof as conversion phosphors.

The invention relates to novel compounds, to mixtures comprising same, to a process for the preparation of these phosphors and mixtures, and to the use thereof as conversion phosphors or in lamps.

LEDs are increasing in importance—both as lighting and also on use as backlighting in liquid-crystal displays (LC displays). These novel light sources have a number of advantages over conventional cold-cathode fluorescent lamps (CCFLs), such as a longer lifetime, potential energy saving, absence of harmful contents (such as mercury in CCFLs).

In the past, for example, arrangements of LEDs which emit blue, green and red light have been employed as backlighting source for LC TV applications. However, this multichip approach has some disadvantages: it is extremely difficult to combine three different chip materials and to ensure uniformity and stability of the light parameters, such as colour point.

pcLEDs (phosphor converted LEDs) have therefore been introduced as light sources for use as backlighting. These usually comprise a green phosphor and a deep-red phosphor together with the blue emission of an LED chip, which are balanced in accordance with the transmission spectra of the colour filter (transmission bands in the blue, green and red region of the spectrum). Theoretically, a construction of this type facilitates colour spaces which are much larger than the usual sRGB. Owing to bottlenecks in the availability of suitable qualities, there is still a demand for further optimised phosphors and/or phosphor mixtures.

In particular, there is a demand for red phosphors. In order to achieve high colour spaces by means of LED TV backlighting, deep-red phosphors which have an emission maximum in the range from 620 nm to 660 nm are necessary. Suitable material systems which are known to the person skilled in the art are siliconitrides and alumosiliconitrides (cf. Xie, Sci. Technol. Adv. Mater. 2007, 8, 588-600): 1-1-2 nitrides, such as, for example, CaSiN₂:Eu²⁺ (Le Toquin, Cheetham, Chem. Phys. Lett. 2006, 423, 352.), 2-5-8 nitrides, such as (Ca,Sr,Ba)₂Si₅N₈:Eu²⁺ (Li et al., Chem. Mater. 2005, 15, 4492) and alumosiliconitrides, such as (Ca,Sr)AlSiN₃:Eu²⁺ (K. Uheda et al., Electrochem. Solid State Lett. 2006, 9, H22).

Nitridic phosphors, as mentioned above, are often complex to prepare and are therefore not available in large quantities or only at very high cost. In particular, the high purity necessary represents a challenge which can only be met with considerable effort in industry. Thus, extremely low concentrations of carbon or oxygen can result in the efficiency of the phosphors being reduced in a sensitive manner. Furthermore, it is desirable to have available materials which are as insensitive as possible to moisture.

It is therefore an object of the present invention to provide materials which emit in the red spectral region and which can be obtained at economically acceptable cost under production conditions or have lower moisture sensitivity compared with known nitridic phosphors.

In the context of this application, red emission or red light denotes light whose intensity maximum has a wavelength between 610 nm and 670 nm, green correspondingly denotes light whose maximum has a wavelength between 508 nm and 550 nm, and yellow denotes light whose maximum has a wavelength between 551 nm and 585 nm.

Surprisingly, it has now been found that certain oxynitrides have phosphor properties comparable to 2-5-8 nitrides, but make significantly lower demands of the preparation process with respect to oxygen content and phase pure purity or have lower sensitivity to moisture.

A first embodiment of the present invention is therefore a compound of the formula I

A_{2-0.5y-x}EuₓSi₅N_{8-y}O_{y} (I)

where A stands for one or more elements selected from Ca, Sr, Ba, and x stands for a value from the range 0.005 to 1, and y stands for a value from the range 0.01 to 3.

The compound of the formula I here can be in the form of a pure substance or a mixture. The present invention therefore furthermore relates to a mixture comprising at least one compound of the formula I, as defined above, and at least one further silicon- and oxygen-containing compound.

It is preferred in accordance with the invention for the at least one further silicon- and oxygen-containing compound to be a reaction by-product of the preparation of the compound of the formula I and for this not to adversely affect the application-relevant optical properties of the compound of the formula I.

The invention therefore furthermore relates to a mixture comprising a compound of the formula I which is obtainable by a process in which, in a step a), suitable starting materials selected from binary nitrides, halides and oxides or corresponding reactive forms thereof are mixed, and, in a step b), the mixture is thermally treated under reductive conditions.

The invention furthermore relates to the corresponding process for the preparation of the compounds of the formula I or the mixtures and to the use according to the invention of the compounds of the formula I or the above-mentioned mixtures as conversion phosphor, in particular for the partial or complete conversion of the blue or near-UV emission of a luminescent diode.

The compounds of the formula I according to the invention and the mixtures above-mentioned mixtures according to the invention are together also referred to below in a simplified manner as phosphors.

The compound of the formula I is usually present in such mixtures in a proportion by weight in the range 30-95% by weight, preferably in the range 50-90% by weight and particularly preferably in the range 60-88% by weight.

In preferred embodiments of the invention, the at least one silicon- and oxygen-containing compound is an X-ray-amorphous or glass-like phase which is distinguished by a high silicon and oxygen content, but may also contain metals, in particular alkaline-earth metals, such as strontium. It may in turn be preferred for these phases to fully or partly surround the particles of the compound of the formula I.

In the compounds of the formula I according to the invention, A in preferred embodiments stands for Sr, while x in preferred embodiments stands for a value from the range 0.01 to 0.8, preferably from the range 0.02 to 0.7 and particularly preferably from the range 0.05 to 0.6 and particularly preferably from the range 0.1 to 0.4, and y in preferred embodiments stands for a value from the range 0.1 to 2.5, preferably from the range 0.2 to 2 and particularly preferably from the range 0.22 to 1.8.

Mixtures or compounds according to the invention, employed in small amounts, already give rise to good LED qualities. The LED quality is described here via conventional parameters, such as, for example, the colour rendering index, the correlated colour temperature, lumen equivalent or absolute lumen, or the colour point in CIE x and CIE y coordinates.

The colour rendering index or CRI is a dimensionless lighting quantity, familiar to the person skilled in the art, which compares the colour reproduction faithfulness of an artificial light source with that of sunlight or and filament light sources (the latter two have a CRI of 100).

The CCT or correlated colour temperature is a lighting quantity, familiar to the person skilled in the art, with the unit kelvin. The higher the numerical value, the colder white light from an artificial radiation source appears to the observer. The CCT follows the concept of the black body radiator, whose colour temperature follows a Planckian curve in the CIE diagram.

The lumen equivalent is a lighting quantity, familiar to the person skilled in the art, with the unit lm/W which describes the magnitude of the photometric luminous flux in lumens of a light source at a certain radiometric radiation power with the unit watt. The higher the lumen equivalent, the more efficient a light source.

The lumen is a photometric lighting quantity, familiar to the person skilled in the art, which describes the luminous flux of a light source, which is a measure of the total visible radiation emitted by a radiation source. The greater the luminous flux, the brighter the light source appears to the observer.

CIE x and CIE y stand for the coordinates in the standard CIE colour chart (here standard observer 1931), familiar to the person skilled in the art, by means of which the colour of a light source is described.

All the indicated mentioned above are calculated from emission spectra of the light source by methods familiar to the person skilled in the art.

In addition, the phosphors according to the invention can be excited over a broad range, extending from about 410 nm to 530 nm, preferably 430 nm to about 500 nm. These phosphors are thus not only suitable for excitation by UV- or blue-emitting primary light sources, such as LEDs or conventional discharge lamps (for example based on Hg), but also for light sources such as those which utilise the blue In³⁺ line at 451 nm.

A further advantage of the phosphors according to the invention is the stability to moisture and water vapour, which can enter the LED package from the environment via diffusion processes and thus reach the surface of the phosphor, and the stability to acidic media, which can arise as by-products during curing of the binder in the LED package or as additives in the LED package. Phosphors which are preferred in accordance with the invention have stabilities which are higher than the nitridic phosphors conventional to date.

In the process according to the invention for the preparation of phosphors according to the invention, suitable starting materials selected from binary nitrides, halides and oxides or corresponding reactive forms thereof are mixed in a step a), and the mixture is thermally treated under reductive conditions in a step b).

In the above-mentioned thermal treatment, it is preferred for this to be carried out at least partly under reducing conditions.

In step b), the reaction is usually carried out at a temperature above 800 C, preferably at a temperature above 1200° C. and particularly preferably in the range 1400° C.-1800° C.

The reductive conditions here are established, for example, using carbon monoxide, forming gas or hydrogen or at least vacuum or an oxygen-deficient atmosphere, preferably in a stream of nitrogen, preferably in a stream of N2/H2 and particularly preferably in a stream of N2/H2/NH3.

If it is intended to prepare the compounds of the formula I in pure form, this can be carried out either via precise control of the starting-material stoichiometry or by mechanical separation of the crystals of the compounds of the formula I from the glass-like fractions. The separation can be carried out, for example, via the different density, particle shape or particle size by separation methods known to the person skilled in the art.

The present invention furthermore relates to a light source having at least one primary light source which comprises at least one phosphor according to the invention. The emission maximum of the primary light source here is usually in the range 410 nm to 530 nm, preferably 430 nm to about 500 nm. A range between 440 and 480 nm is particularly preferred, where the primary radiation is partly or fully converted into longer-wavelength radiation by the phosphors according to the invention.

In a preferred embodiment of the light source according to the invention, the primary light source is a luminescent indium aluminum gallium nitride, in particular of the formula

InᵢGaⱼAlₖN, where 0≦i, 0≦j, 0≦k, and i+j+k=1.

Possible forms of light sources of this type are known to the person skilled in the art. These can be light-emitting LED chips of various structure.

In a further preferred embodiment of the light source according to the invention, the primary light source is a luminescent arrangement based on ZnO, TCO (transparent conducting oxide), ZnSe or SiC or an arrangement based on an organic light-emitting layer (OLED).

In a further preferred embodiment of the light source according to the invention, the primary light source is a source which exhibits electroluminescence and/or photoluminescence. The primary light source may furthermore also be a plasma or discharge source.

Corresponding light sources according to the invention are also known as light-emitting diodes or LEDs.

The phosphors according to the invention can be employed individually or as a mixture with the following phosphors which are familiar to the person skilled in the art. Corresponding phosphors are, for example:

Ba₂SiO₄:Eu²⁺, BaSi₂O₅:Pb²⁺, BaₓSri₁₋ₓF₂:Eu²⁺, BaSrMgSi₂O₇:Eu²⁺, BaTiP₂O₇, (Ba,Ti)₂P₂O₇:Ti, Ba₃WO₆:U, BaY₂F₈:Er³⁺,Yb⁺, Be₂SiO₄:Mn²⁺, Bi₄Ge₃O₁₂, CaAl₂O₄:Ce³⁺, CaLa₄O₇:Ce³⁺, CaAl₂O₄:Eu²⁺, CaAl₂O₄:Mn²⁺, CaAl₄O₇:Pb²⁺,Mn²⁺, CaAl₂O₄:Tb³⁺, Ca₃Al₂Si₃O₁₂:Ce³⁺, Ca₃Al₂Si₃Oi₂:Ce³⁺, Ca₃Al₂Si₃O,₂:Eu²⁺, Ca₂B₅O₉Br:Eu²⁺, Ca₂B₅O₉Cl:Eu²⁺, Ca₂B₅O₉Cl:Pb²⁺, CaB₂O₄:Mn²⁺, Ca₂B₂O₅:Mn²⁺, CaB₂O₄:Pb²⁺, CaB₂P₂O₉:Eu²⁺, Ca₅B₂SiO₁₀:Eu³⁺, Ca_{0.5}Ba_{0.5}Al₁₂O₁₉:Ce³⁺,Mn²⁺, Ca₂Ba₃(PO₄)₃Cl:Eu²⁺, CaBr₂:Eu²⁺ in SiO₂, CaCl₂:Eu²⁺ in SiO₂, CaCl₂:Eu²⁺,Mn²⁺ in SiO₂, CaF₂:Ce³⁺, CaF₂:Ce³⁺,Mn²⁺, CaF₂:Ce³⁺,Tb³⁺, CaF₂:Eu²⁺, CaF₂:Mn²⁺, CaF₂:U, CaGa₂O₄:Mn²⁺, CaGa₄O₇:Mn²⁺, CaGa₂S₄:Ce³⁺, CaGa₂S₄:Eu²⁺, CaGa₂S₄:Mn²⁺, CaGa₂S₄:Pb²⁺, CaGeO₃:Mn²⁺, CaI₂:Eu²⁺ in SiO₂, CaI₂:Eu²⁺,Mn²⁺ in SiO₂, CaLaBO₄:Eu³⁺, CaLaB₃O₇:Ce³⁺,Mn²⁺, Ca₂La₂BO_{6.5}:Pb²⁺, Ca₂MgSi₂O₇, Ca₂MgSi₂O₇:Ce³⁺, CaMgSi₂O₆:Eu²⁺, Ca₃MgSi₂O₈:Eu²⁺, Ca₂MgSi₂O₇:Eu²⁺, CaMgSi₂O₆:Eu²⁺,Mn²⁺, Ca₂MgSi₂O₇:Eu²⁺,Mn²⁺, CaMoO₄, CaMoO₄:Eu³⁺, CaO:Bi³⁺, CaO:Cd²⁺, CaO:Cu⁺, CaO:Eu³⁺, CaO:Eu³⁺, Na⁺, CaO:Mn²⁺, CaO:Pb²⁺, CaO:Sb³⁺, CaO:Sm³⁺, CaO:Tb³⁺, CaO:Tl, CaO:Zn²⁺, Ca₂P₂O₇:Ce³⁺, α-Ca₃(PO₄)₂:Ce³⁺, β-Ca₃(PO₄)₂:Ce³⁺, Ca₅(PO₄)₃Cl:Eu²⁺, Ca₅(PO₄)₃Cl:Mn²⁺, Ca₅(PO₄)₃Cl:Sb³⁺, Ca₅(PO₄)₃Cl:Sn²⁺, β-Ca₃(PO₄)₂:Eu²⁺,Mn²⁺, Ca₅(PO₄)₃F:Mn²⁺, Caₛ(PO₄)₃F:Sb³⁺, Caₛ(PO₄)₃F:Sn²⁺, α-Ca₃(PO₄)₂:Eu²⁺, β-Ca₃(PO₄)₂:Eu²⁺, Ca₂P₂O₇:Eu²⁺, Ca₂P₂O₇:Eu²⁺,Mn²⁺, CaP₂O₆:Mn²⁺, α-Ca₃(PO₄)₂:Pb²⁺, α-Ca₃(PO₄)₂:Sn²⁺, β-Ca₃(PO₄)₂:Sn²⁺, β-Ca₂P₂O₇:Sn,Mn, α-Ca₃(PO₄)₂:Tr, CaS:Bi³⁺, CaS:Bi³⁺,Na, CaS:Ce³⁺, CaS:Eu²⁺, CaS:Cu⁺,Na⁺, CaS:La³⁺, CaS:Mn²⁺, CaSO₄:Bi, CaSO₄:Ce³⁺, CaSO₄:Ce³⁺,Mn²⁺, CaSO₄:Eu²⁺, CaSO₄:Eu²⁺,Mn²⁺, CaSO₄:Pb²⁺, CaS:Pb²⁺, CaS:Pb²⁺,Cl, CaS:Pb²⁺,Mn²⁺, CaS:Pr³⁺,Pb²⁺,Cl, CaS:Sb³⁺, CaS:Sb³⁺,Na, CaS:Sm³⁺, CaS:Sn²⁺, CaS:Sn²⁺,F, CaS:Tb³⁺, CaS:Tb³⁺,Cl, CaS:Y³⁺, CaS:Yb²⁺, CaS:Yb²⁺,Cl, CaSiO₃:Ce³⁺, Ca₃SiO₄Cl₂:Eu²⁺, Ca₃SiO₄Cl₂:Pb²⁺, CaSiO₃:Eu²⁺, CaSiO₃:Mn²⁺,Pb, CaSiO₃:Pb²⁺, CaSiO₃:Pb²⁺,Mn²⁺, CaSiO₃:Ti⁴⁺, CaSr₂(PO₄)₂:Bi³⁺, β-(Ca,Sr)₃(PO₄)₂:Sn²⁺Mn²⁺, CaTi_{0.9}Al_{0.1}O₃:Bi³⁺, CaTiO₃:Eu³⁺, CaTiO₃:Pr³⁺, Ca₅(VO₄)₃Cl, CaWO₄, CaWO₄:Pb²⁺, CaWO₄:W, Ca₃WO₆:U, CaYAlO₄:Eu³⁺, CaYBO₄:Bi³⁺, CaYBO₄:Eu³⁺, CaYB_{0.8}O_{3.7}:Eu³⁺, CaY₂ZrO₆:Eu³⁺, (Ca,Zn,Mg)₃(PO₄)₂:Sn, CeF₃, (Ce,Mg)BaAl₁₁O₁₈:Ce, (Ce,Mg)SrAl₁₁O₁₈:Ce, CeMgAl₁₁O₁₉:Ce:Tb, Cd₂B₆O₁₁:Mn²⁺, CdS:Ag⁺,Cr, CdS:In, CdS:In, CdS:In,Te, CdS:Te, CdWO₄, CsF, CsI, CsI:Na⁺, CsI:Tl, (ErCl₃)_{0.25}(BaCl₂)_{0.75}, GaN:Zn, Gd₃Ga₅O₁₂:Cr³⁺, Gd₃Ga₅O₁₂:Cr,Ce, GdNbO₄:Bi³⁺, Gd₂O₂S:Eu³⁺, Gd₂O₂Pr³⁺, Gd₂O₂S:Pr,Ce,F, Gd₂O₂S:Tb³⁺, Gd₂SiO₅:Ce³⁺, KAl₁₁O₁₇:Tl⁺, KGa₁₁O₁₇:Mn²⁺, K₂La₂Ti₃O₁₀:Eu, KMgF₃:Eu²⁺, KMgF₃:Mn²⁺, K₂SiF₆:Mn⁴⁺, LaAl₃B₄O₁₂:Eu³⁺, LaAlB₂O₆:Eu³⁺, LaAlO₃:Eu³⁺, LaAlO₃:Sm³⁺, LaAsO₄:Eu³⁺, LaBr₃:Ce³⁺, LaBO₃:Eu³⁺, (La,Ce,Tb)PO₄:Ce:Tb, LaCl₃:Ce³⁺, La₂O₃:Bi³⁺, LaOBr:Tb³⁺, LaOBr:Tm³⁺, LaOCl:Bi³⁺, LaOCl:Eu³⁺, LaOF:Eu³⁺, La₂O₃:Eu³⁺, La₂O₃:Pr³⁺, La₂O₂S:Tb³⁺, LaPO₄:Ce³⁺, LaPO₄:Eu³⁺, LaSiO₃Cl:Ce³⁺, LaSiO₃Cl:Ce³⁺,Tb³⁺, LaVO₄:Eu³⁺, La₂W₃O₁₂:Eu³⁺, LiAlF₄:Mn²⁺, LiAl₅O₈:Fe³⁺, LiAlO₂:Fe³⁺, LiAlO₂:Mn²⁺, LiAl₅O₈:Mn²⁺, Li₂CaP₂O₇:Ce³⁺,Mn²⁺, LiCeBa₄Si₄O₁₄:Mn²⁺, LiCeSrBa₃Si₄O₁₄:Mn²⁺, LiInO₂:Eu³⁺, LiInO₂:Sm³⁺, LiLaO₂:Eu³⁺, LuAlO₃:Ce³⁺, (Lu,Gd)₂SiO₅:Ce³⁺, Lu₂SiO₅:Ce³⁺, Lu₂Si₂O₇:Ce³⁺, LuTaO₄:Nb⁵⁺, Lu₁₋ₓYₓAlO₃:Ce³⁺, MgAl₂O₄:Mn²⁺, MgSrAl₁₀O₁₇:Ce, MgB₂O₄:Mn²⁺, MgBa₂(PO₄)₂:Sn²⁺, MgBa₂(PO₄)₂:U, MgBaP₂O₇:Eu²⁺, MgBaP₂O₇:Eu²⁺,Mn²⁺, MgBa₃Si₂O₈:Eu²⁺, MgBa(SO₄)₂:Eu²⁺, Mg₃Ca₃(PO₄)₄:Eu²⁺, MgCaP₂O₇:Mn²⁺, Mg₂Ca(SO₄)₃:Eu²⁺, Mg₂Ca(SO₄)₃:Eu²⁺,Mn², MgCeAlₙO₁₉:Tb³⁺, Mg₄(F)GeO₆:Mn²⁺, Mg₄(F)(Ge,Sn)O₆:Mn²⁺, MgF₂:Mn²⁺, MgGa₂O₄:Mn²⁺, Mg₈Ge₂O₁₁F₂:Mn⁴⁺, MgS:Eu²⁺, MgSiO₃:Mn²⁺, Mg₂SiO₄:Mn²⁺, Mg₃SiO₃F₄:Ti⁴⁺, MgSO₄:Eu²⁺, MgSO₄:Pb²⁺, MgSrBa₂Si₂O₇:Eu²⁺, MgSrP₂O₇:Eu²⁺, MgSr₅(PO₄)₄:Sn²⁺, MgSr₃Si₂O₈:Eu²⁺,Mn²⁺, Mg₂Sr(SO₄)₃:Eu²⁺, Mg₂TiO₄:Mn⁴⁺, MgWO₄, MgYBO₄:Eu³⁺, Na₃Ce(PO₄)₂:Tb³⁺, NaI:Tl, Na_{1.23}K_{0.42}Eu_{0.12}TiSi₄O₁₁:Eu³⁺, Na_{1.23}K_{0.42}Eu_{0.12}TiSi₅O₁₃.xH₂O:Eu³⁺, Na_{1.29}K_{0.46}Er_{0.08}TiSi₄O₁₁:Eu³⁺, Na₂Mg₃Al₂Si₂O₁₀:Tb, Na(Mg₂₋ₓMnₓ)LiSi₄O₁₀F₂:Mn, NaYF₄:Er³⁺, Yb³⁺, NaYO₂:Eu³⁺, P46(70%)+P47 (30%), SrAl₁₂O₁₉:Ce³⁺, Mn²⁺, SrAl₂O₄:Eu²⁺, SrAl₄O₇:Eu³⁺, SrAl₁₂O₁₉:Eu²⁺, SrAl₂S₄:Eu²⁺, Sr₂B₅O₉Cl:Eu²⁺, SrB₄O₇:Eu²⁺(F,Cl,Br), SrB₄O₇:Pb²⁺, SrB₄O₇:Pb²⁺, Mn²⁺, SrB₈O₁₃:Sm²⁺, SrₓBa_{y}Cl_{z}Al₂O_{4-z/2}:Mn²⁺, Ce³⁺, SrBaSiO₄:Eu²⁺, Sr(Cl,Br,I)₂:Eu²⁺ in SiO₂, SrCl₂:Eu²⁺ in SiO₂, Sr₅Cl(PO₄)₃:Eu, Sr_{w}FₓB₄O_{6.5}:Eu²⁺, Sr_{w}FₓB_{y}O_{z}:Eu²⁺,Sm²⁺, SrF₂:Eu²⁺, SrGa₁₂O₁₉:Mn²⁺, SrGa₂S₄:Ce³⁺, SrGa₂S₄:Eu²⁺, SrGa₂S₄:Pb²⁺, SrIn₂O₄:Pr³⁺, Al³⁺, (Sr,Mg)₃(PO₄)₂:Sn, SrMgSi₂O₆:Eu²⁺, Sr₂MgSi₂O₇:Eu²⁺, Sr₃MgSi₂O₈:Eu²⁺, SrMoO₄:U, SrO.3B₂O₃:Eu²⁺,Cl, β-SrO.3B₂O₃:Pb²⁺, β-SrO.3B₂O₃:Pb²⁺,Mn²⁺, α-SrO.3B₂O₃:Sm²⁺, Sr₆P₅BO₂₀:Eu, Sr₅(PO₄)₃Cl:Eu²⁺, Sr₅(PO₄)₃Cl:Eu²⁺,Pr³⁺, Sr₅(PO₄)₃Cl:Mn²⁺, Sr₅(PO₄)₃Cl:Sb³⁺, Sr₂P₂O₇:Eu²⁺, β-Sr₃(PO₄)₂:Eu²⁺, Sr₅(PO₄)₃F:Mn²⁺, Sr₅(PO₄)₃F:Sb³⁺, Sr₅(PO₄)₃F:Sb³⁺,Mn²⁺, Sr₅(PO₄)₃F:Sn²⁺, Sr₂P₂O₇:Sn²⁺, β-Sr₃(PO₄)₂:Sn²⁺, β-Sr₃(PO₄)₂:Sn²⁺,Mn²⁺(Al), SrS:Ce³⁺, SrS:Eu²⁺, SrS:Mn²⁺, SrS:Cu⁺,Na, SrSO₄:Bi, SrSO₄:Ce³⁺, SrSO₄:Eu²⁺, SrSO₄:Eu²⁺,Mn²⁺, Sr₅Si₄O₁₀Cl₆:Eu²⁺, Sr₂SiO₄:Eu²⁺, SrTiO₃:Pr³⁺, SrTiO₃:Pr³⁺,Al³⁺, Sr₃WO₆:U, SrY₂O₃:Eu³⁺, ThO₂:Eu³⁺, ThO₂:Pr³⁺, ThO₂:Tb³⁺, YAl₃B₄O₁₂:Bi³⁺, YAl₃B₄O₁₂:Ce³⁺, YAl₃B₄O₁₂:Ce³⁺,Mn, YAl₃B₄O₁₂:Ce³⁺,Tb³⁺, YAl₃B₄O₁₂:Eu³⁺, YAl₃B₄O₁₂:Eu³⁺,Cr³⁺, YAl₃B₄O₁₂:Th⁴⁺,Ce³⁺,Mn²⁺, YAlO₃:Ce³⁺, Y₃Al₅O₁₂:Ce³⁺, Y₃Al₅O₁₂:Cr³⁺, YAlO₃:Eu³⁺, Y₃Al₅O₁₂:Eu^{3r}, Y₄Al₂O₉:Eu³⁺, Y₃Al₅O₁₂:Mn⁴⁺, YAlO₃:Sm³⁺, YAlO₃:Tb³⁺, Y₃Al₅O₁₂:Tb³⁺, YAsO₄:Eu³⁺, YBO₃:Ce³⁺, YBO₃:Eu³⁺, YF₃:Er³⁺,Yb³⁺, YF₃:Mn²⁺, YF₃:Mn²⁺,Th⁴⁺, YF₃:Tm³⁺,Yb³⁺, (Y,Gd)BO₃:Eu, (Y,Gd)BO₃:Tb, (Y,Gd)₂O₃:Eu³⁺, Y_{1.34}Gd_{0.60}O₃(Eu,Pr), Y₂O₃:Bi³⁺, YOBrEu³⁺, Y₂O₃:Ce, Y₂O₃:Er³⁺, Y₂O₃:Eu³⁺(YOE), Y₂O₃:Ce³⁺,Tb³⁺, YOCl:Ce³⁺, YOCl:Eu³⁺, YOF:Eu³⁺, YOF:Tb³⁺, Y₂O₃:Ho³⁺, Y₂O₂S:Eu³⁺, Y₂O₂S:Pr³⁺, Y₂O₂S:Tb³⁺, Y₂O₃:Tb³⁺, YPO₄:Ce³⁺, YPO₄:Ce³⁺,Tb³⁺, YPO₄:Eu³⁺, YPO₄:Mn²⁺,Th⁴⁺, YPO₄:V⁵⁺, Y(P,V)O₄:Eu, Y₂SiO₅:Ce³⁺, YTaO₄, YTaO₄:Nb⁵⁺, YVO₄:Dy³⁺, YVO₄:Eu³⁺, ZnAl₂O₄:Mn²⁺, ZnB₂O₄:Mn²⁺, ZnBa₂S₃:Mn²⁺, (Zn,Be)₂SiO₄:Mn²⁺, Zn_{0.4}Cd_{0.6}S:Ag, Zn_{0.6}Cd_{0.4}S:Ag, (Zn,Cd)S:Ag,Cl, (Zn,Cd)S:Cu, ZnF₂:Mn²⁺, ZnGa₂O₄, ZnGa₂O₄:Mn²⁺, ZnGa₂S₄:Mn²⁺, Zn₂GeO₄:Mn²⁺, (Zn,Mg)F₂:Mn²⁺, ZnMg₂(PO₄)₂:Mn²⁺, (Zn,Mg)₃(PO₄)₂:Mn²⁺, ZnO:Al³⁺,Ga³⁺, ZnO:Bi³⁺, ZnO:Ga³⁺, ZnO:Ga, ZnO—CdO:Ga, ZnO:S, ZnO:Se, ZnO:Zn, ZnS:Ag⁺,Cl⁻, ZnS:Ag,Cu,Cl, ZnS:Ag,Ni, ZnS:Au,In, ZnS—CdS (25-75), ZnS—CdS (50-50), ZnS—CdS (75-25), ZnS—CdS:Ag,Br,Ni, ZnS—CdS:Ag⁺,Cl, ZnS—CdS:Cu,Br, ZnS—CdS:Cu,I, ZnS:Cl⁻, ZnS:Eu²⁺, ZnS:Cu, ZnS:Cu⁺,Al³⁺, ZnS:Cu⁺,Cl⁻, ZnS:Cu,Sn, ZnS:Eu²⁺, ZnS:Mn²⁺, ZnS:Mn,Cu, ZnS:Mn²⁺,Te²⁺, ZnS:P, ZnS:P³⁻,Cl⁻, ZnS:Pb²⁺, ZnS:Pb²⁺,Cl⁻, ZnS:Pb,Cu, Zn₃(PO₄)₂:Mn²⁺, Zn₂SiO₄:Mn²⁺, Zn₂SiO₄:Mn²⁺,As⁵⁺, Zn₂SiO₄:Mn,Sb₂O₂, Zn₂SiO₄:Mn²⁺,P, Zn₂SiO₄:Ti⁴⁺, ZnS:Sn²⁺, ZnS:Sn,Ag, ZnS:Sn²⁺,Li⁺, ZnS:Te,Mn, ZnS—ZnTe:Mn²⁺, ZnSe:Cu⁺,Cl, ZnWO₄

In an embodiment according to the invention, it is preferred for the light source to comprise a green-emitting phosphor in addition to the phosphor according to the invention. Corresponding phosphors are known to the person skilled in the art or can be selected by the person skilled in the art from the list given above. Green-emitting phosphors which are preferred in accordance with the invention are firstly barium-containing orthosilicate phosphors and secondly luthethium-containing garnet phosphors.

In a particularly preferred embodiment, it is in turn preferred for the phosphors to be arranged on the primary light source in such a way that the phosphor according to the invention is irradiated essentially by light from the primary light source, while the green-emitting phosphor is irradiated essentially by light which has already passed through the red-emitting phosphor or has been scattered thereby. This can be achieved by installing the phosphor according to the invention between the primary light source and the green-emitting phosphor.

The phosphors or phosphor combinations according to the invention can either be dispersed in a resin (for example epoxy or silicone resin) or, in the case of suitable size ratios, arranged directly on the primary light source or alternatively arranged remote therefrom, depending on the application (the latter arrangement also includes “remote phosphor technology”). The advantages of the remote phosphor technology are known to the person skilled in the art and are revealed, for example, by the following publication: Japanese Journ. of Appl. Phys. Vol. 44, No. 21 (2005). L649-L651.

In a further embodiment, it is preferred for the optical coupling between the phosphor and the primary light source to be achieved by a light-conducting arrangement. It is thus possible for the primary light source to be installed at a central location and to be optically coupled to the phosphor by means of light-conducting devices, such as, for example, optical fibres. In this way, it is possible to achieve lamps adapted to the lighting wishes which merely consist of one or various phosphors, which can be arranged to form a light screen, and an optical waveguide, which is coupled to the primary light source. In this way, it is possible to place a strong primary light source at a location which is favourable for electrical installation and to install lamps comprising phosphors which are coupled to the optical waveguides at any desired locations without further electrical cabling, but instead only by laying optical waveguides.

The invention furthermore relates to a lighting unit, in particular for the backlighting of display devices, characterised in that it comprises at least one light source according to the invention, and to a display device, in particular a liquid-crystal display device (LC display), having backlighting, characterised in that it comprises at least one lighting unit according to the invention.

A further aspect of the present invention relates to an electronic or electro-optical device comprising one or more phosphors as described above and below. A further aspect relates to the use of the phosphors as described above and below in an electronic or electro-optical device. The electronic or electro-optical device can also be, for example, an organic field-effect transistor (OFET), a thin-film transistor (TFT), an organic solar cell (O-SC), an organic laser diode (O-laser), an organic integrated circuit (O-IC), an RFID (radio frequency identification) tag, a photodetector, a sensor, a logic circuit, a memory element, a capacitor, a charge-injection layer, a Schottky diode, a planarisation layer, an antistatic film, a conductive substrate or a conductive structure, a photoconductor, an electrophotographic element or an organic light-emitting transistor (OLET).

The particle size of the phosphors according to the invention on use in LEDs is between 50 nm and 30 μm, preferably between 1 μm and 20 μm.

For use in LEDs, the phosphors can also be converted into any desired outer shapes, such as spherical particles, flakes and structured materials and ceramics. These shapes are summarised in accordance with the invention under the term “moulded body”. The moulded body is preferably a “phosphor body”. The present invention thus furthermore relates to a moulded body comprising the phosphors according to the invention.

In a further preferred embodiment, the phosphor moulded body has a structured (for example pyramidal) surface on the side opposite an LED chip (see DE 102006054330), which is incorporated in its full scope into the context of the present application by way of reference). This enables as much light as possible to be coupled out of the phosphor. The structured surface on the phosphor can be produced by subsequent coating with a suitable material which is already structured or in a subsequent step by (photo)lithographic methods, etching methods or by writing methods using energy or material beams or by the action of mechanical forces.

In a further preferred embodiment, the phosphor moulded body according to the invention has, on the side opposite an LED chip, a rough surface which carries nanoparticles comprising SiO₂, TiO₂, Al₂O₃, ZnO₂, ZrO₂ and/or Y₂O₃ or combinations of these materials or comprising particles comprising the phosphor composition. A rough surface here has a roughness of up to a few 100 nm. The coated surface has the advantage that total reflection can be reduced or prevented and the light can be coupled out of the phosphor according to the invention better (see DE 102006054330), which is incorporated in its full scope into the context of the present application by way of reference).

It is furthermore preferred for the phosphor moulded bodies according to the invention to have, on the surface facing away from the chip, a layer of matched refractive index which simplifies coupling-out of the primary radiation and or the radiation emitted by the phosphor body.

In a further preferred embodiment, the phosphors have a continuous surface coating consisting of SiO₂, TiO₂, Al₂O₃, ZnO, ZrO₂ and/or Y₂O₃ or mixed oxides thereof. This surface coating has the advantage that, through a suitable grading of the refractive indices of the coating materials, the refractive index can be matched to the environment. In this case, the scattering of light at the surface of the phosphor is reduced and a greater proportion of the light can penetrate into the phosphor and be absorbed and converted therein. In addition, the refractive index-matched surface coating enables more light to be coupled out of the phosphor since total internal reflection is reduced.

In addition, a continuous layer is advantageous if the phosphor has to be encapsulated. This may be necessary in order to counter sensitivity of the phosphor or parts thereof to diffusing water or other materials in the immediate environment. A further reason for encapsulation with a closed shell is thermal decoupling of the actual phosphor from the heat generated in the chip. This heat results in a reduction in the fluorescence light yield of the phosphor and may also influence the colour of the fluorescence light. Finally, a coating of this type enables the efficiency of the phosphor to be increased by preventing lattice vibrations arising in the phosphor from propagating to the environment.

In addition, it may be preferred for the phosphors to have a porous surface coating consisting of SiO₂, TiO₂, Al₂O₃, ZnO, ZrO₂ and/or Y₂O₃ or mixed oxides thereof or of the phosphor composition. These porous coatings offer the possibility of further reducing the refractive index of a single layer. Porous coatings of this type can be produced by three conventional methods, as described in WO 03/027015, which is incorporated in its full scope into the context of the present application by way of reference: the etching of glass (for example soda-lime glasses (see U.S. Pat. No. 4,019,884)), the application of a porous layer, and the combination of a porous layer and an etching operation.

In a further preferred embodiment, the phosphors have a surface which carries functional groups which facilitate chemical bonding to the environment, preferably consisting of epoxy or silicone resin. These functional groups can be, for example, esters or other derivatives which are bonded via oxo groups and are able to form links to constituents of the binders based on epoxides and/or silicones. Surfaces of this type have the advantage that homogeneous incorporation of the phosphors into the binder is facilitated. Furthermore, the rheological properties of the phosphor/binder system and also the pot lives can thereby be adjusted to a certain extent. Processing of the mixtures is thus simplified.

Since the phosphor layer according to the invention applied to the LED chip preferably consists of a mixture of silicone and phosphor particles, and the silicone has a surface tension, this phosphor layer is not uniform on a microscopic level or the thickness of the layer is not constant throughout.

The preparation of flake-form phosphors as a further preferred embodiment is carried out by conventional processes from the corresponding metal salts and/or rare-earth salts. The preparation process is described in detail in EP 763573 and DE 102006054331, which are incorporated in their full scope into the context of the present application by way of reference. These flake-form phosphors can be prepared by coating a natural or synthetically prepared, highly stable support or a substrate comprising, for example, mica, SiO₂, Al₂O₃, ZrO₂, glass or TiO₂ flakes which has a very large aspect ratio, an atomically smooth surface and an adjustable thickness with a phosphor layer by a precipitation reaction in aqueous dispersion or suspension. Besides mica, ZrO₂, SiO₂, Al₂O₃, glass or TiO₂ or mixtures thereof, the flakes may also consist of the phosphor material itself or be built up from one material. If the flake itself merely serves as support for the phosphor coating, the latter must consist of a material which is transparent to the primary radiation of the LED, or absorbs the primary radiation and transfers this energy to the phosphor layer. The flake-form phosphors are dispersed in a resin (for example silicone or epoxy resin), and this dispersion is applied to the LED chip.

The flake-form phosphors can be prepared on a large industrial scale in thicknesses of 50 nm to about 20 μm, preferably between 150 nm and 5 μm. The diameter here is from 50 nm to 20 μm.

It generally has an aspect ratio (ratio of the diameter to the particle thickness) of 1:1 to 400:1 and in particular 3:1 to 100:1.

The flake dimensions (length×width) are dependent on the arrangement. Flakes are also suitable as centres of scattering within the conversion layer, in particular if they have particularly small dimensions.

The surface of the flake-form phosphor according to the invention facing the LED chip can be provided with a coating which has an antireflection action with respect to the primary radiation emitted by the LED chip. This results in a reduction in back-scattering of the primary radiation, enabling the latter to be coupled better into the phosphor body according to the invention.

Suitable for this purpose are, for example, coatings of matched refractive index, which must have a following thickness d: d=[wavelength of the primary radiation of the LED chip/(4*refractive index of the phosphor ceramic)], see, for example, Gerthsen, Physik [Physics], Springer Verlag, 18th Edition, 1995. This coating may also consist of photonic crystals, which also includes structuring of the surface of the flake-form phosphor in order to achieve certain functionalities.

The production of the phosphors according to the invention in the form of ceramic bodies can be carried out analogously to the process described in DE 102006037730 (Merck), which is incorporated in its full scope into the context of the present application by way of reference. In this process, the phosphor is prepared by wet-chemical methods by mixing the corresponding starting materials and dopants, subsequently subjected to isostatic pressing and applied directly to the surface of the chip in the form of a homogeneous thin and non-porous flake. There is thus no location-dependent variation of the excitation and emission of the phosphor, which means that the LED provided therewith emits a homogeneous light cone of constant colour and has high light output. The ceramic phosphor bodies can be produced on a large industrial scale, for example, as flakes in thicknesses from a few 100 nm to about 500 μm. The flake dimensions (length x width) are dependent on the arrangement. In the case of direct application to the chip, the size of the flake should be selected in accordance with the chip dimensions (from about 100 μm*100 μm to several mm²) with a certain oversize of about 10% to 30% of the chip surface with a suitable chip arrangement (for example flip-chip arrangement) or correspondingly. If the phosphor flake is installed over a finished LED, all of the exiting light cone passes through the flake.

The side surfaces of the ceramic phosphor body can be coated with a light metal or noble metal, preferably aluminum or silver. The metal coating has the effect that light does not exit laterally from the phosphor body. Light exiting laterally can reduce the luminous flux to be coupled out of the LED. The metal coating of the ceramic phosphor body is carried out in a process step after the isostatic pressing to give rods or flakes, where the rods or flakes can optionally be cut to the requisite size before the metal coating. To this end, the side surfaces are wetted, for example, with a solution comprising silver nitrate and glucose and subsequently exposed to an ammonia atmosphere at elevated temperature. A silver coating, for example, forms on the side surfaces in the process.

Alternatively, currentless metallisation processes are also suitable, see, for example, Hollemann-Wiberg, Lehrbuch der Anorganischen Chemie [Textbook of Inorganic Chemistry], Walter de Gruyter Verlag or Ullmanns Enzyklopädie der chemischen Technologie [Ullmann's Encyclopaedia of Chemical Technology].

The ceramic phosphor body can, if necessary, be fixed to the baseboard of an LED chip using a water-glass solution.

In a further embodiment, the ceramic phosphor body has a structured (for example pyramidal) surface on the side opposite an LED chip. This enables as much light as possible to be coupled out of the phosphor body. The structured surface on the phosphor body is produced by carrying out the isostatic pressing using a compression mould having a structured pressure plate and thus embossing a structure into the surface. Structured surfaces are desired if the aim is to produce the thinnest possible phosphor bodies or flakes. The pressing conditions are known to the person skilled in the art (see J. Kriegsmann, Technische keramische Werkstoffe [Industrial Ceramic Materials], Chapter 4, Deutscher Wirtschaftsdienst, 1998). It is important that the pressing temperatures used are ⅔ to ⅚ of the melting point of the substance to be pressed.

The following examples are intended to illustrate the present invention. However, they should in no way be regarded as limiting. All compounds or components which can be used in the compositions are either known and commercially available or can be synthesised by known methods. The temperatures indicated in the examples are always in ° C. It furthermore goes without saying that, both in the description and also in the examples, the added amounts of the components in the compositions always add up to a total of 100%. Percentage data given should always be regarded in the given context. However, they usually always relate to the weight of the part-amount or total amount indicated.

### EXAMPLES

### Example 1

### Preparation of Different Compositions of the Mixture (Ca,Sr,Ba)_{2-0.5y-x}Si₅N_{8-y}O_{y}:Eu(II)ₓ*SiO₂

### Example 1A

### Sr_{1.6}Si₅N_{7.6}O_{0.4}:Eu(II)_{0.2}*2.1 SiO₂

4.2203 g (14.51 mmol) of Sr₃N₂, 0.3074 g (1.85 mmol) of EuN, 0.1163 g (0.92 mmol) of SrF₂ and 1.3911 g (23.15 mmol) of SiO₂ are thoroughly mixed in an agate mortar in a glovebox. The mixture is transferred into a corundum crucible, which is covered with a molybdenum foil and transferred into an oven. There, the mixture is calcined at a temperature of 1600° C. in a stream of N₂/H₂/NH₃ for 8 h. The material is then removed and washed in 1 molar HCl solution for 3 h, filtered off with suction, rinsed with water and dried.

Elemental analysis shows that the material has a lower Sr/Si ratio than Sr₂Si₅N₈ and contains significant amounts of oxygen. The material was measured in a powder X-ray diffractometer (FIG. 1), and the crystal structure was determined by means of Rietveld refinement starting from the Sr₂Si₅N₈ crystal-structure type. The X-ray powder patterns were recorded using a StadiP 611 KL transmission powder X-ray diffractometer from Stoe & Cie. GmbH. The X-ray tube emitted Cu—Kα1 radiation, a germanium [111]-focusing primary ray monochromator and a linear PSD detector were used.

The Rietveld refinement was carried out using the GSAS program (A. C. Larson and R. B. Von Dreele, General Structure Analysis System (GSAS), Los Alamos National Laboratory Report LAUR, 2004, 86-748) with a Thompson, Cox and Hastings pseudo-Voigt (P. Thompson, D. E. Cox and J. B. Hastings, J. Appl. Cryst., 20, 1987, 79-83) reflection profile including correction of asymmetry (“umbrella effect”) by the Finger, Cox and Jephcoat method (L. W. Finger, D. E. Cox and A. P. Jephcoat, J. Appl. Cryst., 27, 1994, 892-900). To this end, firstly the lattice constants, the zero point, the background (including amorphous fraction) and the reflection profile were adjusted in a model-free LeBail refinement, and the parameters of the background and reflection profile were kept constant in the subsequent Rietveld refinement. For the structural model, the europium content obtained from the elemental analysis was correspondingly set proportionately to the strontium atom positions and held there. All atom positions and the associated isotropic deflection parameters were refined freely. The europium occupation factor was coupled to the occupation factor of the strontium positions and refined freely. The sum of the strontium and europium occupation factors was refined reproducibly to values less than 100%. The differences in the measured pattern from the calculated pattern with complete occupation of the Sr/Eu position cannot be explained by other effects such as preferential orientation in the sample (so-called texture effect). A preferential orientation only arises in the case of pronounced morphology of the sample, but the results of a scanning electron photomicrograph do not provide any indication of this. The sample material consists of particles of irregular morphology in the region of a few microns. In addition, the material was comminuted in the mortar before the measurement. The test of a refinement of the preferential orientation using a fourth order spherical harmonics model gave virtually no preferential orientation. For this reason, it was not refined during the determination of the Sr defects. The refinement of the atom positions only resulted in slight movements, and consequently the structural model continues to be chemically and physically acceptable. This and the agreement of the calculated pattern with the measured pattern proves the correctness of the structural model, i.e. the crystal structure determined with the corresponding occupation of the individual atom positions.

The amorphous fraction of the materials was subtracted with the background of the X-ray pattern and therefore plays no role for the determination. To this extent, the Rietveld analysis provides selectively the elemental composition and crystal structure of the crystalline phase. An estimation of the amorphous content from the area ratios in the pattern correlates with the results of the elemental analysis.

The resultant product exhibits the fluorescence spectrum shown in FIG. 2, the excitation spectrum shown in FIG. 3a and the reflection spectrum shown in FIG. 3b.

### Example 1B

### Synthesis of Sr_{1.5}Si₅N_{7.6}O_{0.4}:Eu(II)_{0.3}*2.3 SiO₂

4.0257 g (13.84 mmol) of Sr₃N₂, 0.5301 g (3.19 mmol) of EuN, 0.1146 g (0.91 mmol) of SrF₂ and 1.3707 g (22.81 mmol) of SiO₂ are thoroughly mixed in an agate mortar in a glovebox. The mixture is transferred into a corundum crucible, which is covered with a molybdenum foil and transferred into an oven. There, the mixture is calcined at a temperature of 1600° C. in a stream of N₂/H₂/NH₃ for 8 h. The material is then removed and washed in 1 molar HCl solution for 3 h, filtered off with suction, rinsed with water and dried.

The structural determination was carried out as described in Example 1A and gave the composition indicated.

### Example 1C

### Synthesis of Sr_{1.4}Si₅N_{7.6}O_{0.4}:Eu_{0.4}*2.8 SiO₂

3.8366 g (13.19 mmol) of Sr₃N₂, 0.7463 g (4.50 mmol) of EuN, 0.1130 g (0.90 mmol) of SrF₂ and 1.3509 g (22.48 mmol) of SiO₂ are thoroughly mixed in an agate mortar in a glovebox. The mixture is transferred into a corundum crucible, which is covered with a molybdenum foil and transferred into an oven. There, the mixture is calcined at a temperature of 1600° C. in a stream of N₂/H₂/NH₃ for 8 h. The material is then removed and washed in 1 molar HCl solution for 3 h, filtered off with suction, rinsed with water and dried.

The structural determination was carried out as described in Example 1A and gave the composition indicated.

### Example 1D

### Synthesis of Ba_{1.76}Si₅N_{7.6}O_{0.4}:Eu_{0.04}

6.453 g (14.66 mmol) of Ba₃N₂, 0.166 g (1 mmol) of EuN, 5.666 g (39.583 mmol) of Si₃N₄ and 0.376 g (6.25 mmol) of SiO₂ are thoroughly mixed in an agate mortar in a glovebox. The mixture is transferred into a corundum crucible, which is covered with a molybdenum foil and transferred into an oven. There, the mixture is calcined at a temperature of 1600° C. in a stream of N₂/H₂/NH₃ for 8 h. The material is then removed and washed in 1 molar HCl solution for 3 h, filtered off with suction, rinsed with water and dried.

The structural determination was carried out as described in Example 1A and gave the composition indicated.

### Example 1E

### Synthesis of Ca_{0.35}Sr_{1.41}Si₅N_{7.6}O_{0.4}:Eu_{0.04}

3.42 g (11.76 mmol) of Sr₃N₂, 0.43 g (2.92 mmol) of Ca₃N₂, 0.166 g (1 mmol) of EuN, 5.666 g (39.583 mmol) of Si₃N₄ and 0.376 g (6.25 mmol) of SiO₂ are thoroughly mixed in an agate mortar in a glovebox. The mixture is transferred into a corundum crucible, which is covered with a molybdenum foil and transferred into an oven. There, the mixture is calcined at a temperature of 1600° C. in a stream of N₂/H₂/NH₃ for 8 h. The material is then removed and washed in 1 molar HCl solution for 3 h, filtered off with suction, rinsed with water and dried.

The structural determination was carried out as described in Example 1A and gave the composition indicated.

FIG. 4 shows the colour points of the phosphors from Example 1A (2), Example 1B (3), Example 1C (4), Example 1D (5) and Example 1E (6) in the CIE 1931 colour chart with the Planckian curve for the ideal black radiator (1).

### Example 1F

### Isolation of Sr_{1.6}Si₅N_{7.6}O_{0.4}:Eu(II)_{0.2}*2.1 SiO₂

Crystals of glass-like fractions are separated out of the sample from Example 1A under the microscope. The crystalline fraction is the compound Sr_{1.6}Si₅N_{7.6}O_{0.4}:Eu(II)_{0.2}*2.1 SiO₂.

### Example 2

### LED Application of the Phosphors

Various concentrations of the phosphor are prepared in Dow Corning OE 6550 silicone resin by mixing 5 ml of component A and 5 ml of component B of the silicone with identical amounts of the phosphor, giving the following silicone/phosphor mixing ratios after the two dispersions A and B have been combined by homogenisation using a Speedmixer:
5% by weight of phosphor,
10% by weight of phosphor,
15% by weight of phosphor and
30% by weight of phosphor.

These mixtures are each transferred into an Essemtek dispenser and introduced into empty LED-3528 packages from Mimaki Electronics. After the silicone has cured at 150° C. for 1 h, the LEDs are characterised in lighting terms with the aid of a set-up consisting of components from Instrument Systems: CAS 140 spectrometer and ISP 250 integration sphere. For the measurement, the LEDs are contacted with a current strength of 20 mA at room temperature using a regulatable current source from Keithley. FIG. 5 shows the luminance (in lumen of the converted LED/mW optical power of the blue LED chip) plotted against the CIE x colour point of the converted LED as a function of the phosphor use concentration in the silicone (5, 10, 15 and 30% by weight).

The lumen equivalent is a lighting quantity familiar to the person skilled in the art with the unit lm/W, which describes the magnitude of the photometric luminous flux in lumen of a light source at a certain radiometric radiation power with the unit watt. The higher the lumen equivalent, the more efficient a light source.

The lumen is a photometric lighting quantity familiar to the person skilled in the art which describes the luminous flux of a light source, which is a measure of the total visible radiation emitted by a radiation source. The greater the luminous flux, the brighter the light source appears to the observer.

CIE x and CIE y stand for the coordinates in the standard CIE colour chart (here standard observer 1931), which is familiar to the person skilled in the art, by means of which the colour of a light source is described.

All the quantities indicated above are calculated from emission spectra of the light source by methods familiar to the person skilled in the art.

### Example 3

### Preparation of the Phosphor Lu_{2.97}Al₅O₁₂:Ce_{0.03} (“LuAG”)

387 g of ammonium hydrogencarbonate are dissolved in 4.3 litres of deionised water over the course of 1 h. 148 g of aluminum chloride hexahydrate, 135 g of lutetium chloride hexahydrate and 0.86 g of cerium chloride heptahydrate are dissolved in 2.7 l of deionised water and added dropwise to the hydrogencarbonate solution over the course of 0.75 h. The hydrogencarbonate solution is adjusted to pH 8. The precipitate formed is filtered off with suction and washed, then dried and transferred into an oven.

The precipitate is pre-calcined in air at 1000° C. for 2 hours and subsequently subjected to reductive calcination at 1700° C. for 6 hours. The emission spectrum of the compound is shown in FIG. 1.

### Example 4

### Preparation of Phosphor Mixtures

10 g of Lu_{2.97}Al₅O₁₂:Ce_{0.03} (“LuAG”) are mixed intimately with 1 g of the phosphor from Example 1A.

### Example 5

### Production of a Light-Emitting Diode (“LuAG-Example 1A”)

The phosphor mixture from Example 4 is mixed with a 2-component silicone (OE 6550 from Dow Corning) in a tumble mixer in such a way that equal amounts of the phosphor mixture are dispersed in the two components of the silicone; the total concentration of the phosphor mixture in the silicone is 8% by weight.

5 ml of each of the two phosphor-containing silicone components are mixed homogeneously with one another and transferred into a dispenser. Empty LED packages from OSA optoelectronics, Berlin, which contain a 100 μm2 GaN chip are filled with the aid of the dispenser. The LEDs are then placed in a heating chamber in order to solidify the silicone at 150° C. for 1 h.

### Example 6

### Production of a Light-Emitting Diode in which the Phosphors are Arranged on the Primary Light Source in such a Way that the Red-Emitting Phosphor is Irradiated Essentially by Light from the Primary Light Source, while the Green-Emitting Phosphor is Irradiated Essentially by Light which has Already Passed Through the Red-Emitting Phosphor or has been Scattered Thereby

The phosphor from Example 1A or LuAG is mixed with a 2-component silicone (OE 6550 from Dow Corning) in a tumble mixer in such a way that equal amounts of the phosphor mixture are dispersed in the two components of the silicone. The concentration of the green phosphor in the silicone is 8% by weight of LuAG (premix A) or 1% by weight of phosphor according to Example 1A (premix B).

5 ml of each of the two phosphor-containing silicone components of a premix are mixed homogeneously with one another and transferred into a dispenser. Empty LED packages from OSA optoelectronics, Berlin, which contain a 100 μm2 GaN chip are filled with the aid of the dispenser. Premix B is introduced first. The LEDs are then placed in a heating chamber in order to solidify the silicone at 150° C. for 1 h. Premix A is subsequently introduced, and the silicone is again solidified in the heating chamber.

Examples 2, 4, 5 and 6 can also be carried out analogously with phosphors according to Examples 1B to 1E or other phosphors according to the invention.

### DESCRIPTION OF THE FIGURES

FIG. 1: X-ray powder pattern of Example 1A, measured in a StadiP 611 KL transmission powder X-ray diffractometer from Stoe & Cie. GmbH, Cu—Kα1 radiation, germanium [111]-focusing primary ray monochromator, linear PSD detector.

FIG. 2a: Fluorescence spectrum of the product from Example 1A, recorded using an Edinburgh Instruments FS920 spectrometer at an excitation wavelength of 450 nm (peak wavelength: 635 nm). During the fluorescence measurement, the excitation monochromator is set to the excitation wavelength, and the detector monochromator arranged after the sample is scanned in 1 nm steps between 550 and 850 nm, with the light intensity passing through the detector monochromator being measured.

FIG. 2b: Fluorescence spectrum of the product from Example 1D; the measurement method is analogous to 2a.

FIG. 2c: Fluorescence spectrum of the product from Example 1E; the measurement method is analogous to 2a.

FIG. 3a: Excitation spectrum of the product from Example 1A, recorded using an Edinburgh Instruments FS920 spectrometer. During the excitation measurement, the excitation monochromator is scanned in 1 nm steps between 250 nm and 610 nm, while the fluorescence light from the sample is detected constantly from a wavelength of 610 nm.

FIG. 3b: Reflection spectrum of the product from Example 1A, recorded using an Edinburgh Instruments FS920 spectrometer. During the reflection measurement, the sample is fixed in an integration sphere, and the excitation monochromator and the detector monochromator are scanned synchronously in 1 nm steps over a wavelength range of 250-800 nm, with the light intensity passing through the detector monochromator being measured. The same procedure is carried out on BaSO₄ powder (as reflection standard). The two spectra obtained are then multiplied by one another, giving the quantitative reflection spectrum of the sample.

FIG. 4: CIE 1931 colour chart with the Planckian curve (1) and the colour points of the phosphors from Example 1A (2), Example 1B (3), Example 1C (4), Example 1D (5) and Example 1E (6).

FIG. 5: Lighting characterisation of the LED from Example 2. Produced with the aid of a set-up consisting of components from Instrument Systems: CAS 140 spectrometer and ISP 250 integration sphere. For the measurement, the LEDs are contacted with a current strength of 20 mA at room temperature using a regulatable current source from Keithley (model 2600). The luminance (in lumen of the converted LED/mW optical power of the blue LED chip) is plotted against the CIE x colour point of the converted LED as a function of the phosphor use concentration in the silicone (5, 10, 15 and 30% by weight).

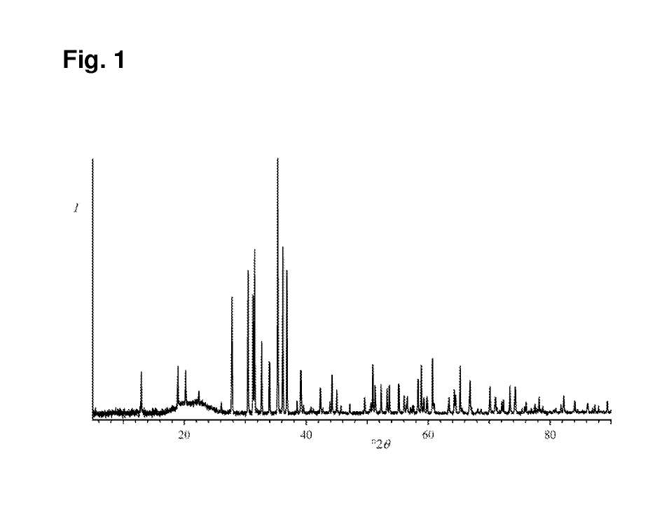

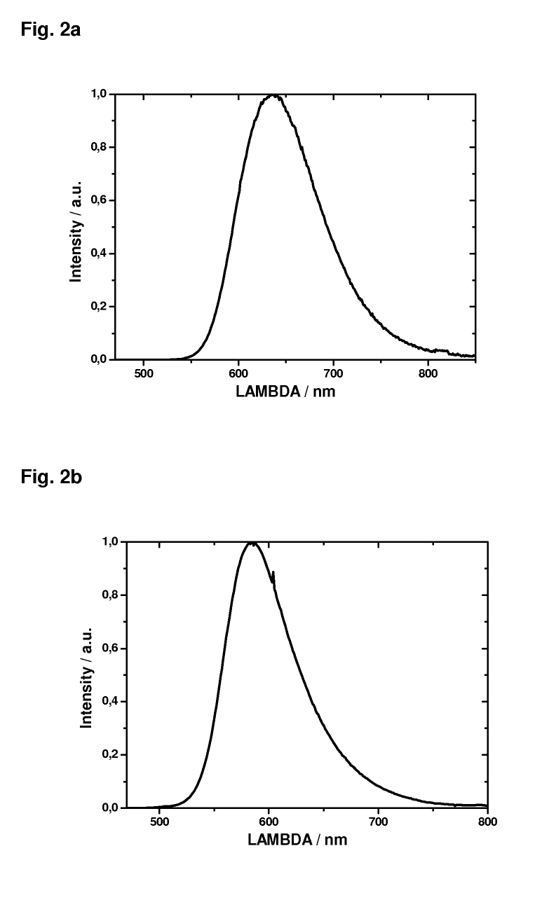

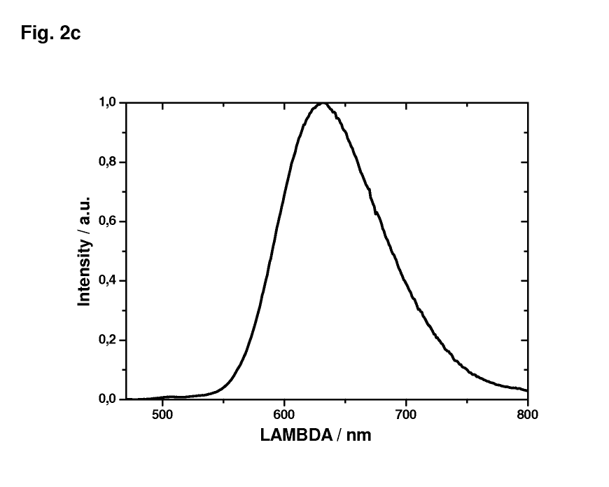

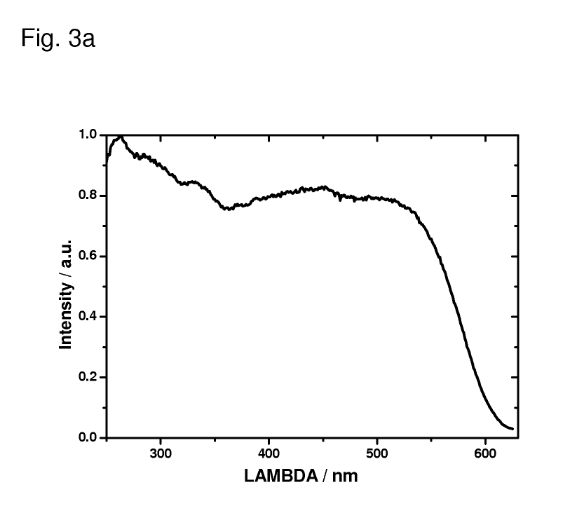

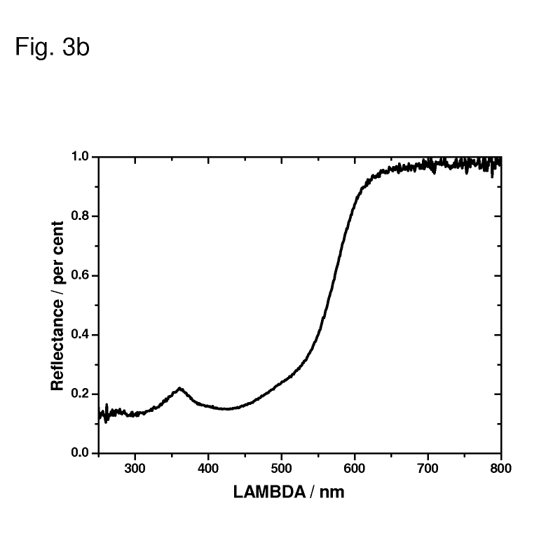

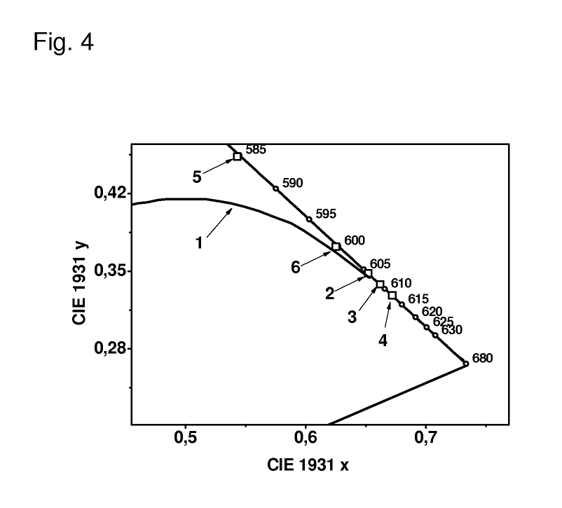

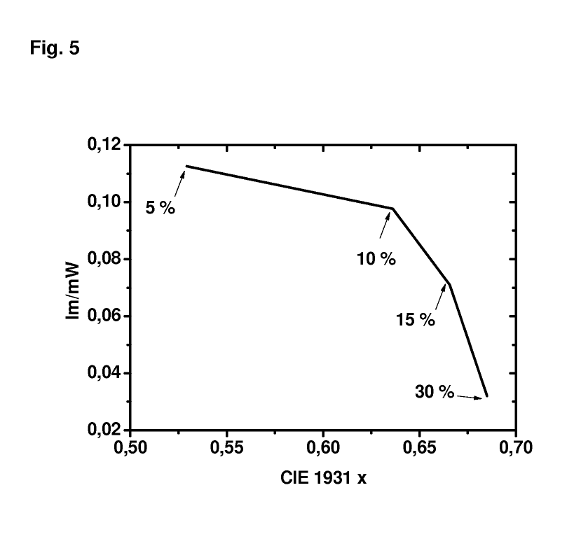

1. Compound of the formula I
A_{2-0.5y-x}EuₓSi₅N_{8-y}O_{y} (I)
where
A stands for one or more elements selected from Ca, Sr, Ba, and
x stands for a value from the range 0.005 to 1, and
y stands for a value from the range 0.01 to 3.

2. Compound according to claim 1, characterised in that A stands for Sr.

3. Compound according to claim 1, characterised in that x stands for a value from the range 0.01 to 0.8, preferably from the range 0.02 to 0.7 and particularly preferably from the range 0.05 to 0.6.

4. Compound according to claim 1, characterised in that y stands for a value from the range 0.1 to 2.5, preferably from the range 0.2 to 2 and particularly preferably from the range 0.22 to 1.8.

5. Compound according to claim 1, characterised in that the compound is in the form of a mixture with a silicon- and oxygen-containing compound.

6. Mixture comprising at least one compound of the formula I
A_{2-0.5y-x}EuₓSi₅N_{8-y}O_{y} (I)
where
A stands for one or more elements selected from Ca, Sr, Ba, and
x stands for a value from the range 0.005 to 1, and
y stands for a value from the range 0.01 to 3 and
at least one further silicon- and oxygen-containing compound.

7. Mixture according to claim 6, characterised in that the compound of the formula I is present in the mixture in a proportion by weight in the range 30-95% by weight, preferably in the range 50-90% by weight and particularly preferably in the range 60-88% by weight.

8. Mixture according to claim 6, characterised in that the mixture is obtainable by a process in which, in a step a), suitable starting materials selected from binary nitrides, halides and oxides or corresponding reactive forms thereof are mixed, and, in a step b), the mixture is thermally treated under reductive conditions.

9. Process for the preparation of a compound according to claim 1, characterised in that suitable starting materials selected from binary nitrides, halides and oxides or corresponding reactive forms thereof are mixed in a step a), and the mixture is thermally treated under reductive conditions in a step b).

10. Process according to claim 9, characterised in that, in step b), the reaction is carried out at a temperature above 800 C, preferably at a temperature above 1200° C. and particularly preferably in the range 1400° C.-1800° C.

11. Process according to claim 9, characterised in that step b) is carried out in a stream of nitrogen, preferably in a stream of N₂/H₂ and particularly preferably in a stream of N₂/H₂/NH₃.

12. Light source having at least one primary light source, characterised in that the light source comprises at least one phosphor according to claim 1.

13. Light source according to claim 12, characterised in that the primary light source is a luminescent indium aluminum gallium nitride, in particular of the formula InᵢGaⱼAlₖN, where 0≦i, 0≦j, 0≦k, and i+j+k=1.

14. Light source according to claim 12, characterised in that the light source comprises a green-emitting phosphor.

15. Light source according to claim 12, characterised in that the phosphors are arranged on the primary light source in such a way that the phosphor of the formula I is irradiated essentially by light from the primary light source, while the green-emitting phosphor is irradiated essentially by light which has already passed through the red-emitting phosphor or has been scattered thereby.

16. Light source according to claim 15, characterised in that the phosphor of the formula I is installed between the primary light source and the green-emitting phosphor.

17. Lighting unit, in particular for the backlighting of display devices, characterised in that it comprises at least one light source according to claim 12.

18. Display device, in particular liquid-crystal display device (LC display), having backlighting, characterised in that it comprises at least one lighting unit according to claim 17.

19. A process for the partial or complete conversion of the blue or near-UV emission of a luminescent diode comprising using a compound according to claim 1 as a conversion phosphor.
